(19) United States
(12) Patent Application Publication
(10) Pub. No.: US 2008/0303129 A1
(43) Pub. Date: Dec. 11, 2008

(54) Patterned contact sheet to protect critical surfaces in manufacturing processes

(76) Inventors: Qing Ya ( Michael) Wang, Shanghai (CN); Junhong Zhang, Fuzhou Fujian (CN)

Correspondence Address: CORNING INCORPORATED, SP-TI-3-1, CORNING, NY, 14831, US

(21) Appl. No.: 11/881,118

(22) Filed: Jul. 25, 2007

Related U.S. Application Data
(60) Provisional application No. 60/934,083, filed on Jun. 11, 2007.

(51) Int. Cl. H01L 23/02; H01L 21/50

(52) U.S. Cl. 257/680; 438/116; 257/E21.499; 257/E23.18

(57) ABSTRACT

The invention is directed a patterned contact sheet and to a method of bonding a cover wafer to an interposer wafer using the patterned contact sheet having a waffle-like pattern of a plurality of ridges and plurality of wells to form a cover/interposer combination or unit that can be bonded to a substrate having a MEMs device thereon, the cover wafer, interposer wafer and substrate together forming a protective packaging for the MEMS. Use of the patterned contact sheet results fewer defects on the window area (the critical area) through which light is transmitted. Surprisingly, use of the patterned contact sheet also results in windows having improved flatness relative to windows made using an unpatterned contact sheet.

### PRIORITY

This application claims the priority of U.S. Provisional Application No. 60/934,083 filed Jun. 11, 2007 in the name of inventors Qing Ya (Michael) Wang and Junhong Zhang and titled “PATTERNED CONTACT SHEET TO PROTECT CRITICAL SURFACES IN MANUFACTURING PROCESSES.”

### FIELD OF THE INVENTION

The invention is directed to a patterned contact sheet to prevent the scratching, staining, impact or otherwise degrading of critical surfaces. The patterned contact sheet is also useful for improving the flatness of the critical areas of the housing window in micromirror devices and other devices that require light to pass through the window.

### BACKGROUND OF THE INVENTION

Certain optical micro-electromechanical (“MEMs”) known as digital micromirror devices (“DMDs”) use a mirror array to reflect incoming light to form an image on a viewing surface. These DMDs require that light be transmitted from outside the device through the cover or lid sealing the device and onto the interior reactive (for example, reflective mirror array) surface of the DMD, and then our of the DMD device to the viewing surface. Each of the devices is individually packaged and sealed to protect it from the outside atmosphere and elements thereof that might affect the DMD's performance and/or lifetime. Since the DMD must receive light to be operative, the cover or lid of the package containing the DMD is made of a material transparent to light; such material preferably being glass because of glass's inertness to moisture, resistance to atmospheric pollutants, durability when exposed to light, superior resistance to damage from, for example, scratches and staining. U.S. Pat. No. 6,856,014 B1 describes a method for sealing a DMD within a package (see FIG. 1). Basically, U.S. Pat. No. 6,856,014 B1 describes a method for individually sealing a plurality of devices that are present on a substrate wafer (for example, a silicon wafer). The sealing is carried out using a light transmissive cover or lid wafer (hereinafter “cover”) having a top exposed to the atmosphere and a bottom, and an interposer wafer (hereinafter “interposer”) having a plurality of open cells or channels through the interposer and a thickness that determines the distance between the top of the device on the substrate and the bottom of the cover or lid. One side the interposer is bonded to the bottom of the cover and the other side of the interposer is bonded to the substrate such that the DMD is contained within a volume defined by the bottom of the cover, the interposer and the substrate (see U.S. Pat. No. 6,856,014 B1). Once the cover, interposer and substrate are bonded to one another, for example, by use of an adhesive, the DMDs on the substrate are separated from one another into individually packages DMDs by sawing through the cover, interposer and substrate. Regarding the interposer, the sawing is done through the material separating the cells or channels (that is, the cell or channel walls) from cover-to-substrate or substrate-to-cover.

In carrying out the packaging of the DMD device, the cover wafer and interposer wafer are bonded together in a first step and then the combined cover/interposer combination is bonded to the substrate in a second step. Using this two-step method, if any damage is done to the critical surface of the cover wafer during bonding of the cover wafer to the interposer, the entire bonded piece can be rejected without suffering the loss (and cost) of the individual DMD devices. FIG. 3 illustrates a set-up 30 in which a cover 40 is bonded to an interposer 60 (the “legs” of which are illustrated by the dotted rectangles) using adhesive 50. The bonding carried out using a chuck 10 as illustrated in FIG. 1. The basic elements of chuck 10 as shown are a frame 12 having top and bottom pieces (not illustrated) and a contact sheet 14 which extends to the edges of frame 12. Part of contact sheet 14 is under the edge area of frame 12 (the shaded area) so that it is held in place during use. Thus, in FIG. 1, only the exposed area of contact sheet 14 is shown and this shown as the circular area “A.” Contact sheet 14 as illustrate in FIG. 1 is unpatterned and “flat.” When chuck 10 is used to bond a cover wafer and an interposer wafer, a cover 40 is placed on the contact sheet 14 within the unshaded area A and the interposer 60 with adhesive 50 thereon is contacted with the cover sheet under a specified pressure to bond the cover and interposer together (see FIG. 3 illustrating the cover 40, adhesive 50, interposer 60 having legs 67, but not the chuck assembly 10). While this method generally works well, nonetheless problems are encountered with scratching and staining (“defects”) of the cover in areas where it is critical that the light entering the cover not encounter any defect that can change the characteristics of the light or refract it. That is, problems can be encountered in the critical areas where light enters and passes though the cover on its way to the DMD element. These problems have been found to be a result of contact between the flat contact sheet 14 and the surface of cover wafer 40 that contacts sheet 14. Consequently, it is highly desirable that an improved method for bonding the cover and the interposer to one another be provided.

### SUMMARY OF THE INVENTION

In one embodiment the invention is directed to a method of bonding a cover wafer to an interposer wafer using a patterned contact sheet to form a cover/interposer combination that can be bonded to a substrate having a MEMs device thereon; the cover wafer, interposer wafer and substrate together forming a protective packaging for the MEMs. The patterned contact sheet 24 as illustrated in FIG. 2, located within and held in place by a chuck, has a plurality of ridges 28 and depressions (or wells) 29 as illustrated in FIG. 6. The cover wafer is placed on top of the patterned contact sheet and an interposer is contacted with the cover wafer, an adhesive being applied to the area where the interposer and cover wafer contact one another to thereby bond the interposer and cover together. The use of the patterned contact sheet is highly effective in reducing the number of defects present on the critical surface of the cover wafer as a result of the bonding process. The patterned contact sheet for bonding the cover wafer to the interposer wafer can be made on any material that does not bond to glass at a pressure of 0.3 MPa or less, preferably a polymeric material. Preferably the patterned contact sheet is made of Teflon®. The patterned contact can also be used when the substrate having the MEMs devices thereon is bonded to the interposer of the cover/interposer combination.

In another embodiment the invention is directed to a patterned contact sheet for use in bonding together a cover wafer and an interposer wafer having a plurality of channels therethrough to make a unit or combination suitable for bonding to a substrate wafer having a plurality of MEMs devices spaced thereon, the contact sheet having a “waffle-like” structure featuring a plurality of ridges and a plurality of wells, the ridges and wells being spaced such that when the interposer wafer, with bonding agent applied thereto, is placed on the cover wafer the bonding surfaces of the interposer wafer are aligned with the ridges of the contact sheet and the cells of the interposer wafer are aligned with the wells of the contact sheet. The patterned contact can also be used when the substrate having the MEMs devices thereon is bonded to the interposer of the cover/interposer combination.

In a further embodiment a second contact sheet that is light transmissive and that has a waffle-like pattern of a plurality of ridges and a plurality of wells can be used for bonding of the cover/interposer combination to the substrate having the MEMs devices thereon. The patterned second contact sheet is in contact with the cover wafer part of the cover/interposer combination during bonding of the cover/interposer to the substrate having the MEMs devices thereon.

In further embodiment the invention is directed to a method for bonding together a cover wafer and an interposer wafer using an adhesive material, the method having at least the steps of:

providing a patterned contact sheet having a plurality of ridges and a plurality of well;

placing a cover wafer on the patterned contact sheet;

supplying an interposer wafer;

applying an adhesive to the interposer wafer surface(s) to be bonded to the cover wafer or applying an adhesive to the cover wafer at a position such that the adhesive on the cover wafer lies only above the ridges of the contact sheet and does not lie above the wells of the contact sheet;

contacting the interposer wafer with the cover wafer such that the surfaces of the interposer wafer that are to be bonded to the cover wafer are aligned with the ridges of the contact sheet and the cells of the interposer are aligned with the wells of the contact sheet;

applying a selected pressure to the cover wafer and the interposer wafer at a selected temperature and for a selected time, with or without the use of actinic radiation, for the adhesive to penetrate micropores of the surface of the cover wafer and the interposer at the positions where they are being bonded and for the adhesive to cure or substantially cure to thereby bond the interposer layer to the cover layer to thereby form a cover/interposer unit or combination; and

removing the bonded cover/interposer unit from contact with the patterned contact sheet; and

optionally, further curing the adhesive by heating to a selected temperature for a selected time or by subjecting the adhesive to actinic radiation.

In a further embodiment the invention is directed to a housing assembly for packaging a micro-electromechanical device, the housing assembly an optically transparent cover layer or window and an interposer layer adhesively bonded together, wherein the window area of the cover has a flatness in the range of 38-76 μm.

### BRIEF DESCRIPTION OF THE DRAWINGS

FIG. 1 illustrates a chuck having a prior art unpatterned contact sheet.

FIG. 2 illustrates a chuck having a patterned contact sheet in accordance with the present invention.

FIG. 3 illustrates the bonding of an interposer wafer 60 to a cover wafer 40 using an adhesive.

FIG. 4 illustrates an one cell of an interposer 60 bonded to a cover wafer and how light hv passes through the cover wafer and the cell of the interposer on its way to a DMD where it is reflected and returned in the reverse direction.

FIG. 5 illustrates a patterned contact sheet, a cover wafer, an interposer, adhesive location between the cover wafer and the interposer and the cell through which light passes.

FIG. 6 is an inverted and simplified representation of FIG. 5 with added details as described herein.

FIG. 7 illustrates the relative flatness of windows made using the patterned contact sheet of the invention as compared to windows made using an unpatterned contact sheet.

### DETAILED DESCRIPTION OF THE INVENTION

As used herein the term “critical surface” or “window” (shown in FIG. 5 as 100) means the surface of a housing or package enclosing an optical MEMs device through which light enters and/or exits to reach the device and/or after being reflected by the device for any purpose; and the term “MEMs device” as used herein means an micro-electromechanical device for manipulating (receiving, reflecting, transmitting, etc.) electromagnetic radiation in the visible, infrared and ultraviolet regions of the electromagnetic spectrum. As also used herein the term “defects” is used as a collective term for scratches, stains, chips, abrasions, impact damage, or any other injury to a critical surface that inhibits, prevents, degrades, distorts or otherwise reduces the performance of a MEMs device relative to one contained in a housing or package whose critical surface is free of such defects. Additionally, the terms “housing” and “packaging” and similar terms can be used interchangeably and refer to a sealed enclosure containing the MEMs device. Further, the term “light” means electromagnetic radiation in the visible, infrared and ultraviolet regions of the electromagnetic spectrum. As used herein the terms “FIG.” and “FIGS.” in all capital letters refers to the figures of U.S. Pat. No. 6,856,014 B1, and the terms “Figure” and Figures” refers to the figures in the drawings accompanying this application. Herein, when a light or actinic radiation transmissive contact sheet is required, the contact sheet, whether patterned or unpatterned, is made of a material transmissive to light or actinic radiation. Examples of such transmissive materials include polymeric materials such as acrylates and methacrylates, polycarbonate and glass. Likewise, when a light transmissive pressure sheet is required the light transmissive pressure sheet is made of similar light transmissive materials.

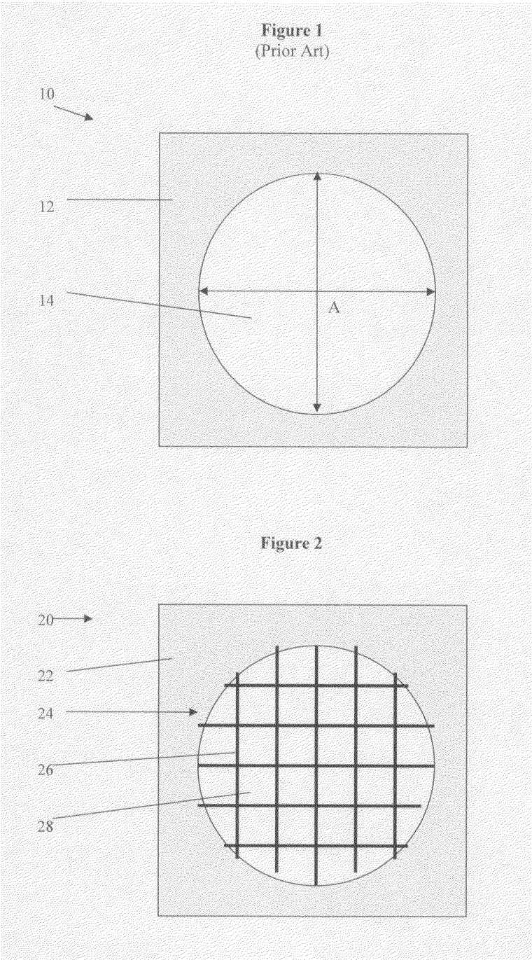

MEMs devices such as are used in projections systems require the use of a housing or packaging to protect the device from substances that can affect and/or degrade the performance of the device such as moisture, smoke, chemicals and other performance-affecting substances. Typically a plurality of MEMs devices are formed on a substrate (for example, a silicon wafer). The individual MEMS devices are enclosed using a combination of a cover wafer and an interposer wafer of a selected size and having a selected thickness with a plurality of cells or channels through said thickness, which cells or channels are separated by cell or channel walls having a thickness, as is described in U.S. Pat. No. 6,856,014 B1 and shown therein in FIG. 1. The cover wafer has a first or top side that will not be bonded to the interposer and a second or bottom side that is bonded to the interposer using a bonding agent, for example, an adhesive The interposer wafer has a first or top side for bonding to the cover wafer and a second or bottom side for bonding to the substrate having the plurality of MEMs devices thereon, and the interposer's plurality of cells extend from the first side to the second side through the thickness of the interposer. Thus the cover wafer first or top side is not bonded to the interposer, the cover wafer second or bottom side is bonded to the interposer first or top side using a bonding agent, for example, an adhesive; and the interposer second or bottom side is bonded to the substrate having the MEMs devices thereon. The cover wafer, the interposer wafer and the substrate wafer are bonded together such that the MEMs devices on the substrate are individually sealed within a volume defined by the substrate, the cells walls of the interposer and the cover wafer. After the individual devices are so sealed. one can use, for example, sawing, scoring and breaking to separate the individual devices as has also described in U.S. Pat. No. 6,856,014 B1. For projection systems, for example, projection televisions, which rely on MEMs devices using a plurality of micromirrors to receive and project images, the surface through which the light enters and exits must be as free from defects as possible so any image that is received and transmitted is undistorted. That is, the surface of the cover layer must be as defect free as possible.

In the process of housing the MEMs devices, for economic reasons and to facilitate the manufacturing process, the cover wafer and the interposer wafer are first bonded together and the resulting cover/interposer combination is then bonded to the substrate wafer such that the interposer wafer lies between the cover wafer and the substrate wafer. FIG. 1 illustrates a chuck assembly 10 having a housing 12 (the housing having upper and lower parts which are not illustrated, the upper part having an opening therethrough) and an unpatterned contact sheet 14. The unpatterned contact sheet 14 is exposed within the upper part of housing 12, the exposed area being circular area A which is defined by the perpendicular double headed arrows. The unpatterned contact sheet 12 also extends between the upper and lower parts of housing 12 so that it will be retained in the housing during use. In use, a cover wafer is placed on the unpatterned sheet 14 area A and the cover wafer is bonded to an interposer wafer using an adhesive which is typically applied to the surface of the interpose wafer that is to be bonded to the cover wafer. Bonding is carried out by applying a selected pressure to the cover wafer and the interposer wafer at a selected temperature and for a selected time, with or without the use of actinic radiation, for the adhesive to penetrate micropores of the surface of the cover wafer and the interposer at the positions where they are being bonded and for the adhesive to cure or substantially cure to thereby bonding the interposer layer to the cover layer to thereby form a cover/interposer combination or unit. In one embodiment the actinic radiation is ultraviolet radiation. The cover wafer and the interposer wafer are made of glass transmissive to light, particularly light in the visible range, and the contact sheet is made of any material that will not bond to glass under a pressure of 0.3 mPa or less. The preferred material for the contact sheet on which the glass cover wafer is positioned for bonding to the interposer is Teflon®.

While the foregoing method of bonding the interposer wafer to the cover wafer works reasonably well, defect such as scratches and stains can occur in critical areas of the cover wafer that are in contact with the unpatterned contact sheet. These can arise from minute particles that accumulate on the contact sheet during the manufacturing process. Consequently, it is highly desirable that an alternative method or element be used during the bonding process.

It has been found that the use of a patterned cover sheet during the bonding process can substantially eliminate cover wafer defects. FIG. 2 illustrates a chuck assembly 20 having a housing 22 (the housing having upper and lower parts which are not illustrated, the upper part having an opening therethrough) and a first patterned contact sheet 24. The first patterned contact sheet 24 (also called herein the “first contact sheet”) is exposed within the upper part of housing 22, the exposed area being circular area Aₚ, area Aₚ being within the circle and illustrated overall as the crosshatched area labeled “Aₚ.” The first patterned contact sheet has a waffle-like pattern of ridges 26 (represented by the dark lines) and wells 28. In one embodiment the patterning is done by CNC (computer numerical controlled) ablation of the contact sheet material, the ablation being carried out such that contact sheet material remains at the bottom of each well. The first contact sheet 22 also extends between the upper and lower parts of chuck 20 frame 22 so that it will be retained in place in the chuck frame during use. The entire contact sheet can be patterned or, in a one embodiment, only that portion of first contact sheet 22 that is exposed within area Aₚ can be patterned, the unpatterned part of the contact sheet lying under the upper part of the housing (the shaded area). In use, a cover wafer is placed on the first patterned sheet 24 area Aₚ and the cover wafer is bonded to an interposer wafer using an adhesive which is typically applied to the surface of the interpose wafer that is to be bonded to the cover wafer. Alternatively, the adhesive can be applied to the cover wafer in areas that overlay the ridges of the first patterned contact sheet. The interposer wafer is positioned such that the open ends of the interposer wafer are positioned over the wells of the first patterned contact sheet and the interposer's cell walls are positioned over the ridges of the patterned contact sheet. The ridges of the contact sheet have dimensions such that they are equal to or lightly thinner than the interposer's cell wall dimensions and the wells of the contact sheet have dimensions such that they are equal to or slightly larger than the interposer's cell dimensions.

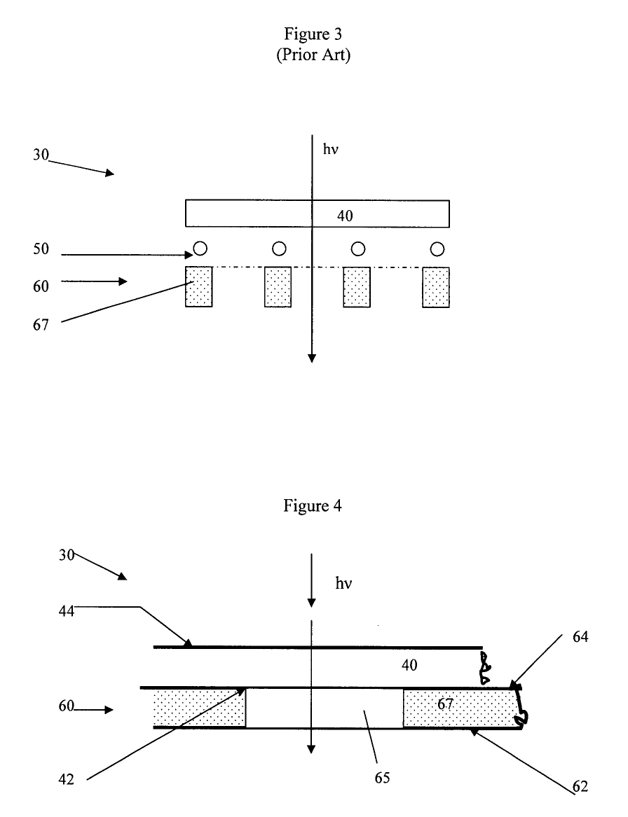

FIG. 3 illustrates, in break-apart form, a cover/interposer combination 30 and shows the positioning of the adhesive 50 between a cover wafer 40 and an interposer 60. The “cells” of the interposer are those portion of the interpose 60 through which light hv will pass to the MEMs device during use such as in a projector. The cell walls of interposer 60 are represented by the patterned rectangles 67 which are connected to one another, for example as represented by the dashed line. Interposer 60 is similar to that shown in U.S. Pat. No. 6,856,014, FIG. 1, as element 26. FIG. 4 illustrates a single cell of the bonded cover/interposer combination 30 of FIG. 3. FIG. 4, numeral 44, represents the side of cover wafer 40 that is in placed in contact with the contact sheet and numeral 42 represents the side that is bonded to the interposer. FIG. 4, numeral 64, represents the side of interposer 60 that is bonded to the cover wafer side 42 by adhesive 50 (not numbered in FIG. 4) and numeral 62 represent the interposer side that is to be bonded to the substrate holding the MEMs devices.

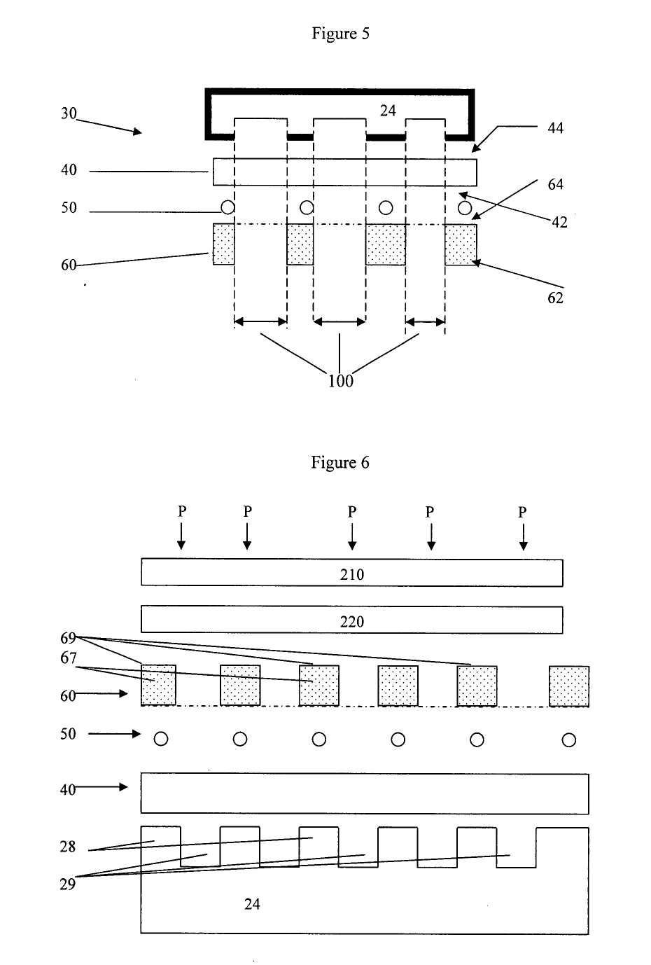

FIG. 5 illustrates the positioning of a cover wafer, the adhesive and the interposer relative to the patterned contact sheet 24 represented by the heavy black lines and showing the wells 29 and ridges 26 of patterned cover sheet 24 (see also FIG. 6). The critical area or window is represented by numeral 100 (dashed lines, extending through interposer wafer 60, cover wafer 40 and ending at the bottom of wells 24a of patterned contact sheet 24). Surfaces 42, 44, 62 and 64 are as explained above regarding FIG. 4. FIG. 6 is a simplified and inverted illustration similar to that in FIG. 4, and addition feature are shown that are used during the bonding process. The patterned contact sheet 24 as shown in FIG. 6 and FIG. 4 is without the chuck housing 12 illustrated in FIGS. 1 and 2.

FIG. 6 further illustrates a second contact sheet 220 which is light transmissive and a light transmissive pressure sheet 210 that are used for applying pressure P is applied to interposer 60 during the bonding process and also to protect the interpose leg surfaces. The second contact sheet 220 and the light transmissive pressure sheet 210 are used to insure that the pressure is uniformly applied and distributed when bonding the interposer wafer to the cover wafer using pressure. Sheets 210 and 220 are both light transmissive so that radiation-curable adhesives can be can be used to bond the cover wafer to the interposer wafer. Sheets 210 and 220 can be made of any material transmissive to the actinic radiation used to cure the adhesive used for bonding. For example, each sheet 210 and 220 can independently be made of silica, fused silica, polycarbonate, an acrylate or other transmissive material. In a preferred embodiment second contact sheet 220 is an acrylate material. In a preferred embodiment the light transmissive pressure sheet 210 is made from fused silica. The second, light transmissive contact sheet 220 can be patterned or unpatterned. FIG. 6 illustrates the use of an unpatterned second contact sheet 220 for bonding interposer wafer 60 to cover wafer 40 using adhesive 50. When a patterned second contact sheet 220 is used the pattern is as illustrated for contact sheet 24 (the first contact sheet). As indicated above, the sheet 210 is used to insure that the bonding pressure is uniformly distributed during the bonding process. In use, the second contact sheet is in contact with the second or bottom side of the interposer wafer (the first or top side of the interposer wafer being used for bonding to the cover wafer with an adhesive) and the pressure sheet is in contact with the second contact sheet. Further, when a patterned second contact sheet 220 is used, the ridges and wells of the second contact sheet 220 are aligned with the ridges and wells of the first contact sheet 24.

A patterned, light transmissive, second contact sheet can also be used during the process of bonding the cover/interposer combination to the substrate having the MEMs devices thereon (as shown in U.S. Pat. No. 6,856,014, FIG. 1) for two reasons. First, when the cover/interposer combination is bonded to the substrate having the MEMs devices thereon, a third, patterned contact sheet that is light transmissive can used to protect the critical surfaces of the cover wafer 40 during this bonding process. Since the third contact sheet will be in contact with the top of the cover wafer of the cover/interposer combination, it is desirable that the critical areas of cover wafer 40 be protected from being scratched, stained or otherwise acquiring defects. Patterning the second contact sheet to have ridges and wells, and positioning the second contact sheet such that the wells of the second contact sheet coincide with the cells of the interposer and the ridges of the second contact sheet coincide with the interposer's cell walls, the second cover sheet will not contact the critical areas of the cover layer during bonding of the cover/interposer combination to the substrate having the MEMs devices thereon. As is the case for the first contact sheet, the ridges of the second contact sheet have dimensions such that they are equal to or slightly thinner than the interposer's cell wall dimensions and the wells of the second contact sheet have dimensions such that they are equal to or slightly larger than the interposer's cell dimensions. This insures that the second contact sheet will not come in contact with the critical areas of the cover wafer. When the cover/interposer combination is bonded to the substrate having the MEMs devices thereon using a radiation curable adhesive the radiation will pass through sheets 210 and 220, cover wafer 40 and interposer 60 to cure the adhesive used for bonding the cover/interposer combination to the substrate. Thus, the ridges and wells of the two cover sheets are aligned and the MEMs-containing substrate and the interposer are also properly aligned so then when the bonding is completed the MEMs device is within a volume defined by the cover, the interposer walls and the substrate.

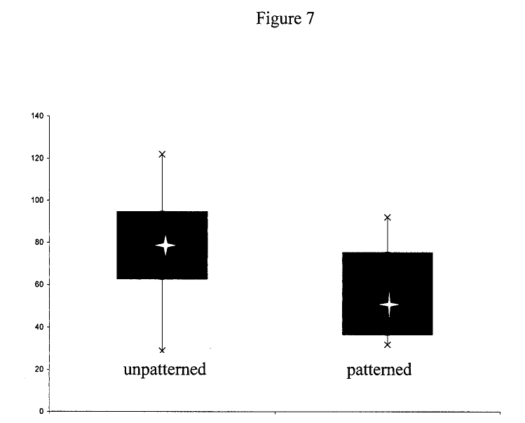

FIG. 7 illustrates an unexpected advantage of using the patterned contact sheet of the invention. The average flatness of the critical area or window 100 as illustrated in FIG. 5 is improved using the patterned contact. Using the unpatterned contact sheet as illustrated in FIG. 1 to bond the cover wafer and the interposer wafer, the average flatness of the resulting windows is 77 μm and the flatness range is 60-94 μm. In contrast, when the patterned contact sheet of the invention as illustrates in FIGS. 2, 5 and 6 is used to bond the cover wafer and the interposer wafer, the average flatness of resulting windows is 57 μm and flatness range is 38-76 μm. Without being held to any particular theory, it is believed that use of the patterned contact sheet results in less bending of the window area during the bonding process and hence an improvement in window flatness. Window flatness is critical to assuring that light is properly transmitted to and from the MEMs device without distortion.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

We claim:

1. A method for bonding a cover wafer to an interposer wafer using an adhesive material, said method having the steps of:
providing a cover wafer transmissive to visible light, an interposer wafer having a thickness and a plurality of channels through the thickness, and an adhesive;
providing a chuck having a patterned contact sheet having a waffle-like pattern of a plurality of ridges and a plurality of wells;
positioning the cover wafer on the patterned contact sheet; and
bonding the interposer wafer to the cover wafer using with the adhesive;
wherein the interposer wafer is positioned over the cover wafer such that the thickness of the interposer's channel walls are aligned with the contact sheet ridges and the interposer's channels are aligned with the contact sheet's wells.

2. The method according to claim 1 wherein the adhesive is thermally cured to bond the cover wafer to the interposer wafer.

3. The method according to claim 1 wherein the adhesive is cured using actinic radiation to bond the cover wafer to the interposer wafer.

4. The method according to claim 1 wherein the adhesive is cured using ultraviolet radiation to bond the cover wafer to the interposer wafer.

5. A method for bonding together a cover wafer and an interposer wafer using an adhesive material, the method having at least the steps of:
providing a chuck having a patterned contact sheet having a plurality of ridges and a plurality of wells;
placing a cover wafer on the patterned contact sheet;
providing an interposer wafer having a thickness and a plurality of channels through the thickness;
applying an adhesive to the interposer wafer surface to be bonded to the cover wafer or alternatively applying an adhesive to the cover wafer at a position such that the adhesive on the cover wafer lies only above the ridges of the contact sheet and does not lie above the wells of the contact sheet;
contacting the interposer wafer with the cover wafer such that the surfaces of the interposer wafer that are to be bonded to the cover wafer are aligned with the ridges of the contact sheet and the channels of the interposer are aligned with the wells of the contact;
applying a selected pressure to the cover wafer and the interposer wafer at a selected temperature and for a selected time, with or without the use of actinic radiation, for the adhesive to penetrate micropores of the surface of the cover wafer and the interposer at the positions where they are being bonded and for the adhesive to cure or substantially cure to thereby bonding the interposer layer to the cover layer to thereby form a cover/interposer unit;
removing the bonded cover/interposer unit from contact with the patterned contact sheet.

6. The method according to claim 5, wherein, optionally, after removal of the bonded cover/interposer from contact with the patterned contact sheet the adhesive is further cured using actinic radiation.

7. The method according to claim 5, wherein, optionally, after removal of the bonded cover/interposer from contact with the patterned contact sheet the adhesive is further cured using ultraviolet radiation.

8. A method for bonding together a cover wafer and an interposer wafer using an adhesive material, the method having at least the steps of:
providing a chuck having a patterned contact sheet having a plurality of ridges and a plurality of wells;
providing a cover wafer having a first side and a second side;
placing the first side of the cover wafer on the patterned contact sheet;
providing an interposer wafer having a first side and a second side and a thickness with a plurality of channels through the thickness;
applying an adhesive to the interposer wafer first side or alternatively applying an adhesive to the cover wafer second side at a position such that the adhesive on the cover wafer lies only above the ridges of the contact sheet and does not lie above the wells of the contact sheet;
contacting the interposer wafer first side with the cover wafer second side such that the surfaces of the interposer wafer that are to be bonded to the cover wafer are aligned with the ridges of the contact sheet and the channels of the interposer are aligned with the wells of the contact;
placing a second, light transmissive patterned contact sheet in contact with the second side of said interposer;
placing a light transmissive pressure sheet in contact with said second contact sheet;
applying a selected pressure to the cover wafer and the interposer wafer at a selected temperature and for a selected time, with or without the use of actinic radiation, to thereby bonding the interposer layer to the cover layer to form a cover/interposer unit;
removing the pressure, the second contact sheet and the pressure sheet; and
removing the bonded cover/interposer unit from contact with the patterned contact sheet to obtain a bonded cover/interposer unit.

9. The method according to claim 8, wherein the actinic radiation is applied during the application of the selected pressure.

10. A housing assembly for packaging a micro-electromechanical device attached to a substrate having said microelectronic device thereon, the housing assembly comprising a cover and an interposer having a thickness with channels therethrough adhesively bonded together to form a cover/interposer combination and said cover having a window area transmissive to light,
wherein when said cover/interposer combination together the window area of the cover has a flatness in the range of 38-76 μm.
